(19) United States
(12) Patent Application Publication
(10) Pub. No.: US 2025/0057018 A1
(43) Pub. Date: Feb. 13, 2025

(54) DISPLAY DEVICE AND METHOD OF MANUFACTURING THE SAME

(71) Applicant: Samsung Display Co., LTD., Yongin-si (KR)

(72) Inventors: TAEYOUNG SONG, Yongin-si (KR); JINWON KIM, Yongin-si (KR); HYE-JIN PAEK, Yongin-si (KR)

(21) Appl. No.: 18/636,622

(22) Filed: Apr. 16, 2024

(30) Foreign Application Priority Data
Aug. 7, 2023 (KR) 10-2023-0102829

(51) Int. Cl. H10K 59/80; H10K 59/12; H10K 59/122; H10K 59/35; H10K 102/00

(52) U.S. Cl. CPC H10K 59/877; H10K 59/1201; H10K 59/122; H10K 59/353; H10K 2102/331

(57) ABSTRACT

A display device includes: a substrate including first to third light emitting areas, which emit light of different colors, respectively, a light emitting element layer on the substrate and overlapping the first to third light emitting areas, a first light control pattern on the light emitting element layer and overlapping the first light emitting area, where the first light control pattern includes a first base resin and first quantum dots dispersed therein, a second light control pattern on the light emitting element layer and overlapping the second light emitting area, a third light control pattern on the light emitting element layer and overlapping the third light emitting area, and a bank layer between the first and third light control patterns and including a part inclined at an angle toward the third light control pattern. The bank layer surrounds the first, second, and third light control patterns in a plan view.

This application claims priority to Korean Patent Application No. 10-2023-0102829, filed on Aug. 7, 2023, and all the benefits accruing therefrom under 35 U.S.C. § 119, the content of which in its entirety is herein incorporated by reference.

### BACKGROUND

### 1. Field

Embodiments provide generally to a display device and a method of manufacturing the display device. More particularly, embodiments relate to a display device that provides visual information and a method of manufacturing the display device.

### 2. Description of the Related Art

As information technology develops, the importance of display devices, which are communication media between users and information, is being highlighted. Accordingly, display devices such as a liquid crystal display device, an organic light emitting display device, a plasma display device, and the like are widely used in various fields.

Recently, an organic light emitting display device including an organic light emitting element and a light control layer are being studied. In such an organic light emitting display device, the light control layer may convert the wavelength of light emitted from the organic light emitting element. Accordingly, the organic light emitting display device may emit light having a different color from the incident light.

### SUMMARY

Embodiments provide a display device capable of implementing high resolution.

Embodiments provide a method of manufacturing the display device.

A display device according to embodiments of the disclosure includes a substrate including a first light emitting area, a second light emitting area, and a third light emitting area, where the first to third light emitting areas emit light of different colors, respectively, a light emitting element layer disposed on the substrate and overlapping the first, second, and third light emitting areas, a first light control pattern disposed on the light emitting element layer and overlapping the first light emitting area, where the first light control pattern includes a first base resin and first quantum dots dispersed in the first base resin, a second light control pattern disposed on the light emitting element layer and overlapping the second light emitting area, a third light control pattern disposed on the light emitting element layer and overlapping the third light emitting area, and a bank layer including a first part inclined at a first angle toward the third light control pattern with respect to a plane parallel to an upper surface of the substrate and located between the first light control pattern and the third light control pattern, where the bank layer surrounds the first, second, and third light control patterns in a plan view.

In an embodiment, the bank layer may further include a second part located the second light control pattern and the third light control pattern, and inclined at a second angle toward the third light control pattern with respect to the plane parallel to the upper surface of the substrate.

In an embodiment, each of the first and second angles may be greater than or equal to about 60 degrees and less than about 90 degrees.

In an embodiment, a part of the bank layer located between the first light control pattern and the second light control pattern may be perpendicular to the upper surface of the substrate.

In an embodiment, a first opening in which the first light control pattern is disposed, a second opening in which the second light control pattern is disposed, and a third opening in which the third light control pattern is disposed may be defined in the bank layer. In such an embodiment, an area of a first bottom surface of the first opening may be smaller than an area of a first top surface of the first opening in the plan view. In such an embodiment, an area of a second bottom surface of the second opening may be smaller than an area of a second top surface of the second opening in the plan view. In such an embodiment, an area of a third bottom surface of the third opening may be larger than an area of a third top surface of the third opening in the plan view.

In an embodiment, a cross-section of the third light control pattern may have a tapered shape.

In an embodiment, a width of a lower part of a part of the bank layer located between the first, second, and third light control patterns may be the same as a width of an upper part of the part of the bank layer located between the first, second, and third light control patterns.

In an embodiment, the first light emitting area may be a red light emitting area which emits red light, the second light emitting area may be a green light emitting area which emits green light, and the third light emitting area may be a blue light emitting area which emits blue light.

In an embodiment, the second light control pattern may include a second base resin and second quantum dots dispersed in the second base resin.

In an embodiment, the third light control pattern may include a base resin including a transparent organic material and scattering particles dispersed in the base resin.

In an embodiment, the first light emitting area, the second light emitting area, and the third light emitting area may be repeatedly arranged in each row line in an order of the first light emitting area, the second light emitting area, and the third light emitting area.

In an embodiment, the second light emitting areas may be repeatedly arranged along a first direction in an odd-numbered row line, the first light emitting area and the third light emitting area may be repeatedly arranged along the first direction in an even-numbered row line in an order of the first light emitting area and the third light emitting area, and the second light emitting area may face the third light emitting area in a second direction crossing the first direction.

A display device according to embodiments of the disclosure includes a substrate including a first light emitting area, a second light emitting area, and a third light emitting area, where the first to third light emitting areas emit light of different colors, respectively, a light emitting element layer disposed on the substrate and overlapping the first, second, and third light emitting areas, a first light control pattern disposed on the light emitting element layer and overlapping the first light emitting area, where the first light control pattern includes a first base resin and first quantum dots dispersed in the first base resin, a second light control pattern disposed on the light emitting element layer and overlapping the second light emitting area, a third light control pattern disposed on the light emitting element layer and overlapping the third light emitting area, and a bank layer surrounding the first, second, and third light control patterns in a plan view, where the bank layer includes: a first part inclined at a first angle toward the third light control pattern with respect to a plane parallel to an upper surface of the substrate and located between the first light control pattern and the third light control pattern, and a second part inclined at a second angle toward the second light control pattern with respect to the plane parallel to the upper surface of the substrate and located between the first light control pattern and the second light control pattern.

In an embodiment, each of the first and second angles may be greater than about 60 degrees and less than about 90 degrees.

In an embodiment, a first opening in which the first light control pattern is disposed, a second opening in which the second light control pattern is disposed, and a third opening in which the third light control pattern is disposed may be defined in the bank layer. In such an embodiment, an area of a first bottom surface of the first opening may be smaller than an area of a first top surface of the first opening in the plan view. In such an embodiment, an area of a second bottom surface of the second opening may be larger than an area of a second top surface of the second opening in the plan view. In such an embodiment, an area of a third bottom surface of the third opening may be larger than an area of a third top surface of the third opening in the plan view.

In an embodiment, a cross-section of each of the second and third light control patterns may have a tapered shape.

In an embodiment, each of the second and third light control patterns may include a base resin including a transparent organic material and scattering particles dispersed in the base resin.

In an embodiment, the first light emitting area, the second light emitting area, and the third light emitting area may be repeatedly arranged in each row line in an order of the first light emitting area, the second light emitting area, and the third light emitting area. The second light emitting area and the third light emitting area may be repeatedly arranged in each row line in an order of the second light emitting area and the third light emitting area. The first light emitting area may be located between the second and third light emitting areas.

A display device according to embodiments of the disclosure includes forming a light emitting element layer on a substrate to overlap a first light emitting area, a second light emitting area, and a third light emitting area of the substrate, where the first to third light emitting areas emit light of different colors, respectively, forming a third light control pattern on the light emitting element layer to overlap the third light emitting area, forming a bank layer on the light emitting element layer, where the bank layer includes a part contacting a side surface of the third light control pattern and inclined at predetermined angle toward the third light control pattern with respect to a plane parallel to an upper surface of the substrate, forming a first light control pattern on the light emitting element layer to overlap the first light emitting area, where the first light control pattern includes a first base resin and first quantum dots dispersed in the first base resin, and forming a second light control pattern area on the light emitting element layer to overlap the second light emitting.

In an embodiment, each of the forming the first light control pattern and the forming the second light control pattern may include using an inkjet process, and the forming the third light control pattern may include using a photolithography process.

A display device according to embodiments of the disclosure may include a first light control pattern overlapping a first light emitting area which emits red light, a second light control pattern overlapping a second light emitting area which emits green light, a third light control pattern overlapping a third light emitting area which emits blue light, and a bank layer surrounding the first, second, and third light control patterns. In such embodiments, a part of the bank layer may be inclined at a predetermined angle toward a light control pattern formed through a photolithography process which does not include quantum dots. Accordingly, in a process of forming a light control pattern through an inkjet process, a sufficient inkjet impact margin can be secured in the inkjet process, such that a high-resolution display device can be implemented.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment of the disclosure.

FIG. 2 is a cross-sectional view taken along line I-I′ of FIG. 1.

FIG. 3 is a plan view illustrating the display device of FIGS. 1 and 2.

FIG. 4 is a cross-sectional view taken along line II-II′ of FIG. 3.

FIG. 5 is a cross-sectional view illustrating first, second, and third light control patterns of FIG. 4.

FIG. 6 is a plan view illustrating a pixel defining layer of FIG. 4.

FIG. 7 is a plan view illustrating an example of the bank layer of FIG. 4.

FIG. 8 is a graph illustrating the impact margin versus the angle at which the bank layer is tilted.

FIGS. 9, 10, 11, 12, 13, 14, 15, 16, and 17 are cross-sectional views illustrating an embodiment of the method of manufacturing the display device of FIG. 4.

FIG. 18 is a plan view illustrating another example of the bank layer of FIG. 4.

FIG. 19 is a plan view illustrating a display device according to an embodiment of the disclosure.

FIG. 20 is a cross-sectional view taken along line III-III′ of FIG. 19.

FIG. 21 is a plan view illustrating an example of the bank layer of FIG. 20.

FIG. 22 is a plan view illustrating a display device according to an embodiment of the disclosure.

FIG. 23 is a plan view illustrating an example of a bank layer.

FIG. 24 is a plan view illustrating another example of a bank layer.

FIG. 25 is a cross-sectional view illustrating another example of FIG. 4.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device and a method of manufacturing the display device according to embodiments of the disclosure will be described in detail with reference to the accompanying drawings. The same reference numerals are used for the same components in the drawings, and any repetitive detailed descriptions of the same components will be omitted or simplified.

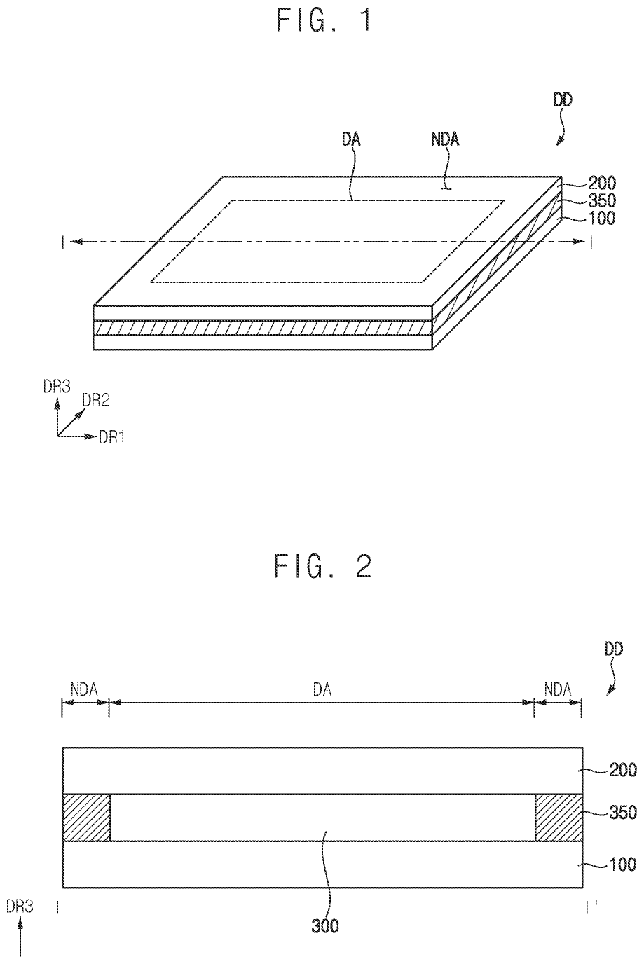

FIG. 1 is a perspective view illustrating a display device according to an embodiment of the disclosure. FIG. 2 is a cross-sectional view taken along line I-I′ of FIG. 1.

Referring to FIGS. 1 and 2, the display device DD according to an embodiment of the disclosure may include a lower structure 100, a sealing portion 350, a filling layer 300, and an upper structure 200.

The display device DD may be divided into a display area DA and a non-display area NDA. The display area DA may be an area which displays an image, and the non-display area NDA may be an area that does not display an image. The non-display area NDA may be located around the display area DA. In an embodiment, for example, the non-display area NDA may surround the display area DA.

The lower structure 100 may include a semiconductor element (e.g., a transistor) which generates a driving current and a light emitting element that is electrically connected to the semiconductor device and generates light based on the driving current. Detailed features of the lower structure 100 will be given later.

The upper structure 200 may be disposed on the lower structure 100. The upper structure 200 may be disposed opposite to the lower structure 100. The upper structure 200 may include a color filter layer which selectively transmits light having a specific wavelength. Detailed features of the upper structure 200 will be described later.

The sealing portion 350 may be disposed between the lower structure 100 and the upper structure 200 in the non-display area NDA. The sealing portion 350 may be disposed along the edges of the lower structure 100 and the upper structure 200 in the non-display area NDA and surround the display area DA in a plan view or when viewed in a third direction DR3. In addition, the lower structure 100 and the upper structure 200 may be coupled through the sealing portion 350. The sealing portion 350 may include an organic material. In an embodiment, for example, the sealing portion 350 may include an epoxy resin or the like. However, the embodiments of the disclosure are not limited, and the sealing portion 350 may include at least one selected from other various organic materials.

The filling layer 300 may be disposed between the lower structure 100 and the upper structure 200. The filling layer 300 may fill a space between the lower structure 100 and the upper structure 200. The filling layer 300 may include a material having light transparency. In an embodiment, for example, the filling layer 300 may include an organic material. Examples of materials that can be used in the filling layer 300 may include silicone-based resin, epoxy-based resin, and the like. These can be used alone or in combination with each other. However, the embodiments of the disclosure are not limited, and the filling layer 300 may include at least one selected from other various organic materials. In other embodiments, the filling layer 300 may be omitted.

In this specification, a plane may be defined as a first direction DR1 and a second direction DR2 crossing the first direction DR1. For example, the second direction DR2 may be perpendicular to the first direction DR1. In addition, the third direction DR3 may be a direction perpendicular to the plane or a thickness direction of the display device DD.

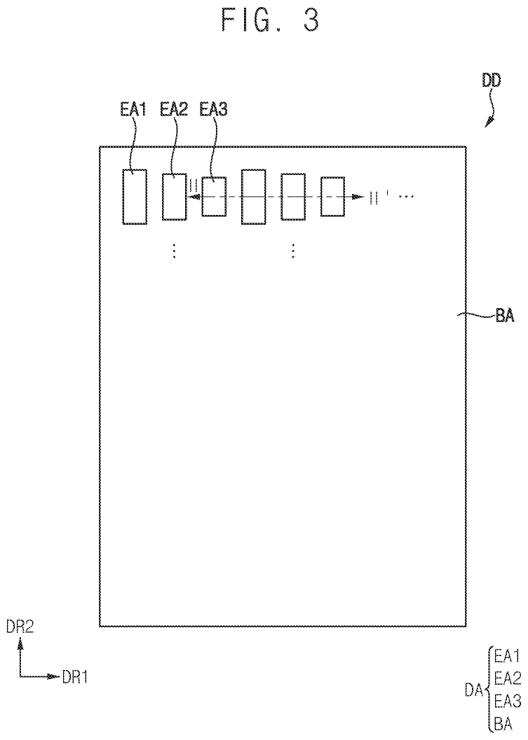

FIG. 3 is a plan view illustrating the display device of FIGS. 1 and 2.

Referring to FIGS. 1, 2, and 3, as described above, an embodiment of the display device DD may be divided into the display area DA and the non-display area NDA. The display area DA may include a plurality of light emitting areas and a light blocking area BA. Each of the light emitting areas may emit light.

The light emitting areas may include a first light emitting area EA1, a second light emitting area EA2, and a third light emitting area EA3.

Each of the first light emitting area EA1, the second light emitting area EA2, and the third light emitting area EA3 may be an area where light emitted from the light emitting element is emitted to the outside. The first light emitting area EA1, the second first light emitting area EA2, and the third first light emitting area EA3 may emit light of different colors, respectively. In an embodiment, for example, the first light emitting area EA1 may emit light of a first color, the second light emitting area EA2 may emit light of a second color, and the third light emitting area EA3 may emit light of a third color.

In an embodiment, the first light emitting area EA1 may be a red light emitting area which emits red light, the second light emitting area EA2 may be a green light emitting area which emits green light, and the third light emitting area EA3 may be a blue light emitting area. which emits blue light. However, the embodiments of the disclosure are not limited thereto. In another embodiment, for example, the first light emitting area EA1, the second light emitting area EA2, and the third light emitting area EA3 may be combined to emit yellow, cyan, and magenta lights.

In addition, the first light emitting area EA1, the second light emitting area EA2, and the third light emitting area EA3 may emit light of four or more colors. In an embodiment, for example, the first light emitting area EA1, the second light emitting area EA2, and the third light emitting area EA3 may be combined to emit at least one selected from yellow, cyan, and magenta lights in addition to red, green, and blue lights. In addition, the first light emitting area EA1, the second light emitting area EA2, and the third light emitting area EA3 may be combined to emit white light.

The first light emitting area EA1, the second light emitting area EA2, and the third light emitting area EA3 may be repeatedly formed or defined along the first direction DR1 and the second direction DR2 crossing the first direction DR1. In an embodiment, the first light emitting area EA1, the second light emitting area EA2, and the third light emitting area EA3 may be repeatedly arranged along each row line in an order of the first light emitting area EA1, the second light emitting area EA2, and the third light emitting area EA3. In an embodiment, for example, the first light emitting area EA1, the second light emitting area EA2, and the third light emitting area EA3 may be repeatedly arranged in the first direction DR1 along a first row line in an order of the first light emitting area EA1, the second light emitting area EA2, and the third light emitting area EA3. In such an embodiment, the first light emitting area EA1, the second light emitting area EA2, and the third light emitting area EA3 may be arranged in the first direction DR1 along a second row line adjacent to the first row line in an order of the first light emitting area EA1, the second light emitting area EA2, and the third light emitting area EA3. This arrangement may be repeated up to a predetermined row line.

The areas of the first light emitting area EA1, the second light emitting area EA2, and the third light emitting area EA3 may be different from each other. In an embodiment, the area of the first light emitting area EA1 which emits red light may be larger than each of the area of the second light emitting area EA2 which emits green light and the area of the third light emitting area EA3 which emits blue light. In this case, the area of the second light emitting area EA2 may be larger than the area of the third light emitting area EA3. However, embodiments of the disclosure are not limited thereto.

The light blocking area BA may be located between the first light emitting area EA1, the second light emitting area EA2, and the third light emitting area EA3. In an embodiment, for example, in the plan view, the light blocking area BA may surround the first light emitting area EA1, the second light emitting area EA2, and the third light emitting area EA3. The light blocking area BA might not emit light.

The display device DD may have a rectangular planar shape. In an embodiment, for example, the display device DD may include two first sides extending in the first direction DR1 and two second sides extending in the second direction DR2. A corner where the first side and the second side meet may be right angles. Alternatively, a corner where the first side and the second side of the display device DD meet may form a curved surface. However, embodiments of the disclosure are not limited thereto.

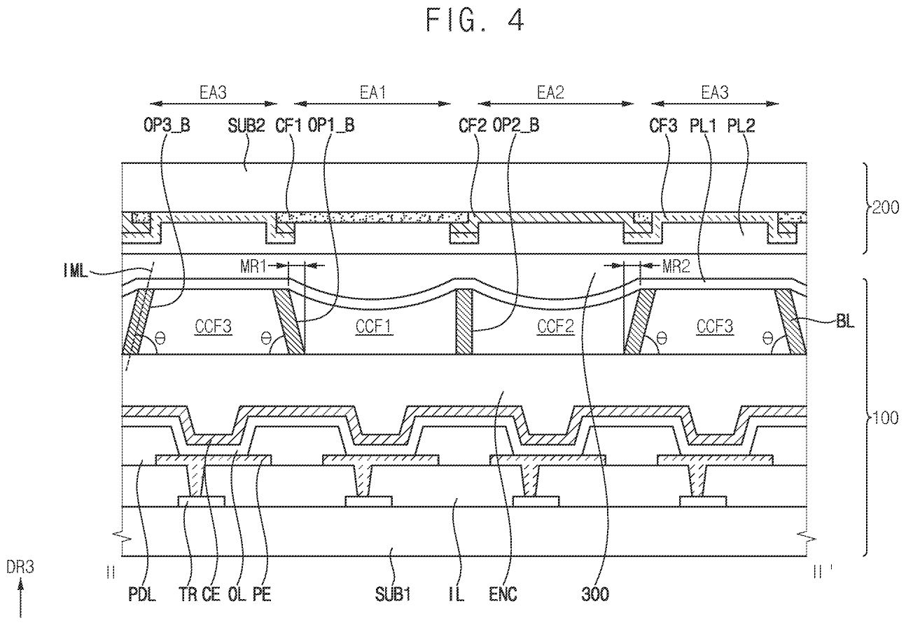

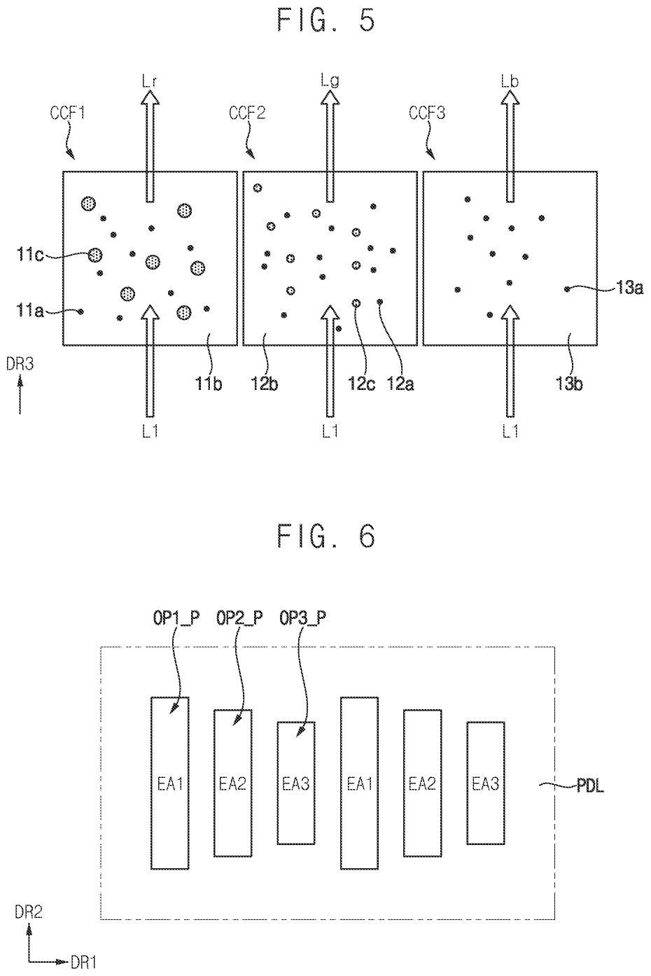

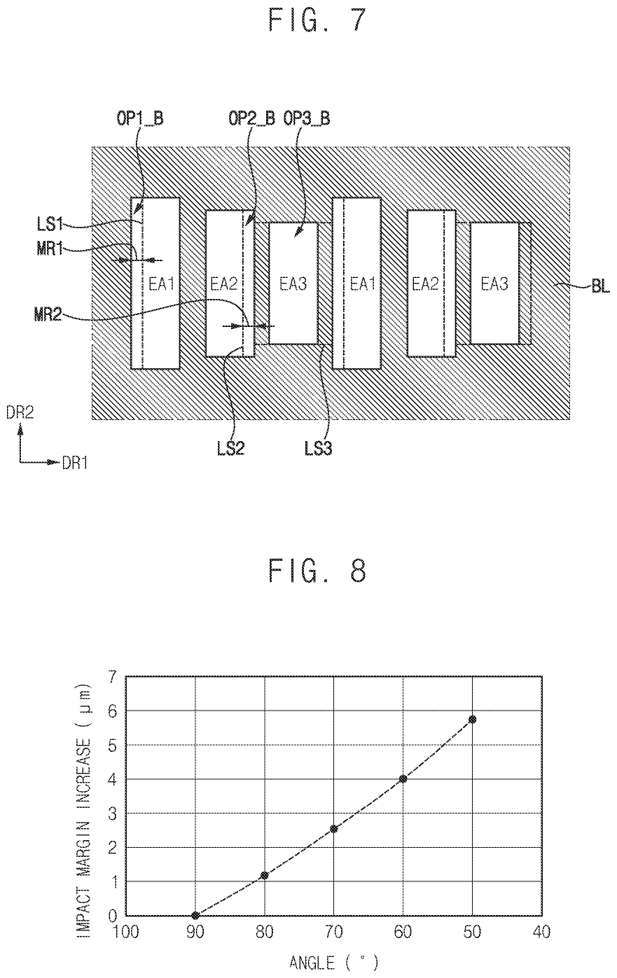

FIG. 4 is a cross-sectional view taken along line II-II′ of FIG. 3. FIG. 5 is a cross-sectional view for explaining first, second, and third light control patterns of FIG. 4. FIG. 6 is a plan view illustrating a pixel defining layer of FIG. 4. FIG. 7 is a plan view illustrating an example of the bank layer of FIG. 4.

Referring to FIGS. 4 and 5, the display device DD according to an embodiment of the disclosure may include the lower structure 100, the filling layer 300, and the upper structure 200. First, the lower structure 100 will be described.

The lower structure 100 may include a first substrate SUB1, a semiconductor element TR, an insulating structure IL, a pixel defining layer PDL, a pixel electrode PE, an organic layer OL, a common electrode CE, an encapsulation layer ENC, a bank layer BL, a light control layer, and a first protective layer PL1.

In an embodiment, as described above, the display device DD may include the display area DA and the non-display area NDA, and the display area DA may include the first light emitting area EA1, the second light emitting area EA2, the third light emitting area EA3, and the light blocking area BA. In such an embodiment where the display area DA of the display device DD includes the first light emitting area EA1, the second light emitting area EA2, the third light emitting area EA3, and the light blocking area BA, the first substrate SUB1 may also include the first light emitting area EA1, the second light emitting area EA2, the third light emitting area EA3, and the light blocking area BA.

The first substrate SUB1 may include a transparent material or an opaque material. The first substrate SUB1 may include or be made of a transparent resin substrate. Examples of the transparent resin substrate may include a polyimide substrate. In this case, the polyimide substrate may include a first organic layer, a first barrier layer, a second organic layer, or the like. Alternatively, the first substrate SUB1 may include a quartz substrate, a synthetic quartz substrate, a calcium fluoride substrate, a fluorine-doped quartz substrate, a soda-lime glass substrate, non-alkali glass substrate, or the like. These can be used alone or in combination with each other.

The semiconductor element TR may be disposed on the first substrate SUB1. In an embodiment, for example, the active layer of the semiconductor element TR may include amorphous silicon, polycrystalline silicon, or a metal oxide semiconductor. In an embodiment, the semiconductor element TR may be a thin film transistor.

The metal oxide semiconductor may include a two-component compound (ABₓ), a three-component compound (ABₓC_{y}), a four-component compound (ABₓC_{y}D_{z}), or the like, which includes indium (In), zinc (Zn), gallium (Ga), tin (Sn), titanium (Ti), aluminum (Al), hafnium (Hf), zirconium (Zr), magnesium (Mg), or the like. In an embodiment, for example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), or the like. These can be used alone or in combination with each other.

The insulating structure IL may be disposed on the first substrate SUB1. The insulating structure IL may cover the semiconductor element TR. The insulating structure IL may include at least one inorganic insulating layer and at least one organic insulating layer.

In an embodiment, for example, the inorganic insulating layer may include silicon oxide (SiOₓ), silicon nitride (SiNₓ), silicon carbide (SiCₓ), silicon oxynitride (SiOₓN_{y}), silicon oxycarbide (SiOₓC_{y}), or the like. These can be used alone or in combination with each other.

In an embodiment, for example, the organic insulating layer may include photoresist, polyacryl-based resin, polyimide-based resin, polyamide-based resin, siloxane-based resin, acryl-based resin, epoxy-based resin, or the like. These can be used alone or in combination with each other.

The pixel electrode PE may be disposed on the insulating structure IL. A plurality of pixel electrodes PE may be provided, and each of the plurality of pixel electrodes PE may overlap the first light emitting area EA1, the second light emitting area EA2, and the third light emitting area EA3. The pixel electrode PE may be connected to the semiconductor element TR through a contact hole defined through the insulating structure IL. In an embodiment, for example, the pixel electrode PE may include metal, alloy, metal nitride, conductive metal oxide, transparent conductive material, or the like. These can be used alone or in combination with each other. The pixel electrode PE may act as an anode.

The pixel defining layer PDL may be disposed on the insulating structure IL and the pixel electrode PE. The pixel defining layer PDL may cover the edge of the pixel electrode. The pixel defining layer PDL may include organic materials and/or inorganic materials. In an embodiment, the pixel defining layer PDL may include an organic material. In an embodiment, for example, the pixel defining layer PDL may include photoresist, polyacrylic-based resin, polyimide-based resin, polyamide-based resin, siloxane-based resin, acrylic-based resin, epoxy-based resin, or the like. These can be used alone or in combination with each other. In another embodiment, the pixel defining layer PDL may include an inorganic material and/or an organic material containing a light blocking material such as black pigment, black dye, or the like.

Referring further to FIG. 6, a first opening OP1_P overlapping the first light emitting area EA1, a second opening OP2_P overlapping the second light emitting area EA2, and a third opening OP3_P overlapping the third light emitting area EA3 may be defined in the pixel defining layer PDL. The first, second, and third openings OP1_P, OP2_P, and OP3_P may each expose at least a part of the upper surface of the pixel electrode PE.

In an embodiment, for example, in the plan view, the area of the first opening OP1_P may be smaller than the area of the first light emitting area EA1, the area of the second opening OP2_P may be smaller than the area of the second light emitting area EA2, and the area of the third opening OP3_P may be smaller than the area of the third light emitting area EA3. However, the embodiments of the disclosure are not limited to this, and in the plan view, the area of the first opening OP1_P may be substantially the same as (or similar to) the area of the first light emitting area EA1, the area of the second opening OP2_P may be substantially the same as (or similar to) the area of the second light emitting area EA2, and the area of the third opening OP3_P may be substantially the same as (or similar to) the area of the third light emitting area EA3.

The organic layer OL may be disposed on the pixel electrode PE and the pixel defining layer PDL. The organic layer OL may be disposed on an entire surface of the display area DA. In an embodiment, for example, the organic layer OL may include a hole transport layer, a hole injection layer, an organic light emitting layer, an electron transport layer, an electron injection layer, etc. The organic light emitting layer may be disposed in the first, second, and third light emitting areas EA1, EA2, and EA3, respectively.

The organic light emitting layer may include an organic material that emits light of a preset color. In an embodiment, for example, the organic light emitting layer may include a plurality of organic light emitting layers sequentially stacked. In an embodiment, the organic light emitting layer may include at least one blue organic light emitting layer which generates blue light and a green organic light emitting layer which generates green light.

The common electrode CE may be disposed on the organic layer OL. The common electrode CE may be disposed on the entire surface of the display area DA. In an embodiment, for example, the common electrode CE may include metal, alloy, metal nitride, conductive metal oxide, transparent conductive material, or the like. These can be used alone or in combination with each other. The common electrode CE may act as a cathode.

In such an embodiment, a light emitting element layer may be defined collectively by the pixel electrode PE, the organic layer OL, and the common electrode CE. The light emitting element layer may be electrically connected to the semiconductor element TR.

The encapsulation layer ENC may be disposed on the common electrode CE. The encapsulation layer ENC may effectively prevent impurities, moisture, external air, or the like from penetrating into the organic light emitting element from the outside. The encapsulation layer ENC may include at least one inorganic layer and at least one organic layer. In an embodiment, for example, the inorganic layer may include silicon oxide, silicon nitride, silicon oxynitride, or the like. These can be used alone or in combination with each other. The organic layer may include a cured polymer such as polyacrylate.

The bank layer BL may be disposed on the encapsulation layer ENC. The bank layer BL may overlap a light blocking area (e.g., the light blocking area BA in FIG. 3). A space capable of accommodating materials forming the first, second, and third light control patterns CCF1, CCF2, and CCF3 may be defined in the bank layer BL.

The bank layer BL may include an inorganic material and/or an organic material. In an embodiment, for example, the bank layer BL may include an organic material such as polyimide. Alternatively, the bank layer BL may include an organic material containing a light blocking material such as black pigment, black dye, or the like. Alternatively, the bank layer BL may include a metal material (e.g., metal, alloy, metal oxide, metal nitride, or the like).

In an embodiment, a first opening OP1_B overlapping the first light emitting area EA1, a second opening OP2_B overlapping the second light emitting area EA2, and a third opening OP3_B overlapping the third light emitting area EA3 may be defined in the bank layer BL.

The light control layer may be disposed on the encapsulation layer ENC. The light control layer may convert the wavelength of light emitted from the light emitting element layer. The light control layer may include a first light control pattern CCF1, a second light control pattern CCF2, and a third light control pattern CCF3. The first light control pattern CCF1 may overlap the first light emitting area EA1, the second light control pattern CCF2 may overlap the second light emitting area EA2, and the third light control pattern CCF3 may overlap the third light emitting area EA3. In an embodiment, the first light control pattern CCF1 may be disposed in the first opening OP1_B, the second light control pattern CCF2 may be disposed in the second opening OP2_B, and the third light control pattern CCF3 may be disposed in the third opening OP3_B.

In an embodiment, a cross-section of the third light control pattern CCF3 may have a tapered shape having a width decreasing as being away from the encapsulation layer ENC or the first substrate SUB1.

In an embodiment, where the bank layer BL includes an organic material, a metal layer may be further disposed between the bank layer BL and the third light control pattern CCF3. In another embodiment, where the bank layer BL includes an organic material, a metal layer may be further disposed between the bank layer BL and the first light control pattern CCF1, and between the bank layer BL and the second light control pattern CCF2, and between the bank layer BL and the third light control pattern CCF3.

In an embodiment, as shown in FIG. 5, the first light control pattern CCF1 may include first quantum dots 11c which are excited by the light L1 emitted from the light emitting element layer and emit light of a first color (e.g., red light Lr). In addition, the first light control pattern CCF1 may further include a first base resin 11b in which first scattering particles (or scatterers) 11a are dispersed. The first quantum dots 11c may also be dispersed in the first base resin 11b.

The second light control pattern CCF2 may include second quantum dots 12c which are excited by the light L1 emitted from the light emitting element layer and emit light of a second color (e.g., green light Lg). In addition, the second light control pattern CCF2 may further include a second base resin 12b in which second scattering particles 12a are dispersed. The second quantum dots 12c may also be dispersed in the second base resin 12b.

The third light control pattern CCF3 may emit blue light Lb by transmitting the light L1 emitted from the light emitting element layer. In addition, the third light control pattern CCF3 may include a third base resin 13b in which third scattering particles 13a are dispersed.

In an embodiment, for example, each of the first, second, and third base resins 11b, 12b, and 13b may include a transparent organic material, i.e., an organic material with high light transparency, such as photoresist, silicone resin, epoxy resin, or the like. These can be used alone or in combination with each other.

In an embodiment, for example, the first, second, and third scattering particles 11a, 12a, and 13a may scatter and emit light emitted from the first, second, and third light emitting elements LED1, LED2, and LED3. In addition, the first, second, and third scattering particles 11a, 12a, and 13a may include a same material as each other.

Accordingly, in such an embodiment, the first light emitting area EA1 may emit red light Lr, the second light emitting area EA2 may emit green light Lg, and the third may emit area EA3 may emit blue light Lb.

A part of the bank layer BL may be inclined at a predetermined angle θ with respect to a plane parallel to an upper surface of the first substrate SUB1. In an embodiment, the bank layer BL may include a first part located between the first light control pattern CCF1 and the third light control pattern CCF3 and inclined at the predetermined angle θ toward the third light control pattern CCF3, and a second part located between the second light control pattern CCF2 and the third light control pattern CCF3 and inclined at the predetermined angle θ toward the third light control pattern CCF3. That is, since the side surface of the third light control pattern CCF3 has a tapered shape, the first part and the second part of the bank layer BL may be inclined at the predetermined angle θ.

Specifically, the predetermined angle θ may be defined as the angle between an imaginary line IML passing through a center of the first part (or the second part) of the bank layer BL and parallel to the side surface of the first part (or the second part) of the bank layer BL, and a plane parallel to the upper surface of the first substrate SUB1.

In an embodiment, the predetermined angle θ may be less than about 90 degrees. That is, the predetermined angle θ may be an acute angle. In an embodiment, the predetermined angle θ may be greater than or equal to about 60 degrees and less than about 90 degrees. If the predetermined angle θ is less than about 60 degrees, the emission efficiency of the third light emitting area EA3 may decrease. If the predetermined angle θ is greater than 90 degrees, the inkjet impact margin may not be secured.

A part of the bank layer BL may be perpendicular to the upper surface of the first substrate SUB1. In an embodiment, a part of the bank layer BL located between the first light control pattern CCF1 and the second light control pattern CCF2 may be perpendicular to the upper surface of the first substrate SUB1. That is, the part of the bank layer BL located between the first light control pattern CCF1 and the second light control pattern CCF2 may be not inclined with respect to a plane parallel to the upper surface of the first substrate SUB1.

A part of the bank layer BL may have a lower width and an upper width that are substantially the same as each other. In an embodiment, the width of a lower part of the part of the bank layer BL located between the first, second, and third light control patterns CCF1, CCF2, and CCF3 may be substantially the same as the width of an upper part of the part of the bank layer BL located between the first, second, and third light control patterns CCF1, CCF2, and CCF3. That is, the width of the part of the bank layer BL located between the first, second, and third light control patterns CCF1, CCF2, and CCF3 may be constant. Accordingly, color mixing between the first, second, and third light emitting areas EA1, EA2, and EA3 may be effectively prevented.

Referring further to FIG. 7, in the plan view, the area of a first bottom surface LS1 of the first opening OP1_B may be different from the area of a first top surface of the first opening OP1_B, the area of a second bottom surface LS2 of the second opening OP2_B may be different from the area of a second top surface of the second opening OP2_B, and the area of a third bottom surface LS3 of the third opening OP3_B may be different from the area of a third top surface of the third opening OP3_B. In an embodiment, the area of the first bottom surface LS1 of the first opening OP1_B may be smaller than the area of the first top surface of the first opening OP1_B, the area of the second bottom surface LS2 of the second opening OP2_B may be smaller than the area of the second top surface of the second opening OP2_B, and the area of the third bottom surface LS3 of the third opening OP3_B may be larger than the area of the third top surface of the third opening OP3_B. Here, a bottom surface and a top surface of an opening may mean the uppermost portion and the lowermost portion of the opening.

Here, the edge of the third bottom surface LS3 may coincide or be aligned with the edge of the first top surface and the edge of the second top surface located in the left and right of the third opening OP3.

In an embodiment, for example, in the plan view, the first top surface may protrude from the side surface of the first bottom surface LS1 in a direction opposite to the first direction DR1, the second top surface may protrude from the side surface of the second bottom surface LS2 in the first direction DR1, and the third bottom surface LS3 may protrude from both side surfaces of the third top surface in the first direction DR1 and in the direction opposite to the first direction DR1. However, embodiments of the disclosure are not limited thereto.

In the plan view, a first interval MR1, where the first top surface of the first opening OP1_B protrudes from the side surface of the first bottom surface LS1, may refer to the inkjet impact margin increase which can be secured in the inkjet process of forming the first light control pattern CCF1, and a second interval MR2, where the second top surface of the second opening OP2_B protrudes from the side surface of the second bottom surface LS2, may refer to the inkjet impact margin increase which can be secured in the inkjet process of forming the second light control pattern CCF2. The first interval MR1 may refer to the shortest distance between the edge of the first top surface and the side surface of the first bottom surface LS1, and the second interval MR2 may refer to the shortest distance between the edge of the second top surface and the side surface of the second bottom surface LS2.

Here, the bottom surface of the opening refers to the surface in contact with the encapsulation layer ENC, and the area of the top surface of the opening refers to the area of the opening.

The first protective layer PL1 may be disposed on the bank layer BL and the light control layer. The first protective layer PL1 may be disposed along the profile of the bank layer BL and the light control layer. The first protective layer PL1 may serve to prevent moisture penetration to prevent deterioration of the light control layer. to the shortest distance example, the first protective layer PL1 may include an inorganic material such as silicon oxide, silicon nitride, silicon oxynitride, or the like. These can be used alone or in combination with each other.

Hereinafter, the upper structure 200 will be described.

The upper structure 200 may include a second substrate SUB2, a color filter layer, and a second protective layer PL2.

The second substrate SUB2 may include or be made of a transparent resin substrate. The second substrate SUB2 may transmit light emitted from the light emitting element layer. In an embodiment, for example, the second substrate SUB2 may include an insulating material such as glass or plastic. Alternatively, the second substrate SUB2 may include an organic polymer material such as polycarbonate (PC), polyethylene (PE), polypropylene (PP), or the like. These can be used alone or in combination with each other.

The color filter layer may be disposed under the second substrate SUB2. The color filter layer can selectively transmit light having a specific wavelength. The color filter layer may include a first color filter CF1, a second color filter CF2, and a third color filter CF3.

The first color filter CF1 may selectively transmit light of the first color (e.g., red light Lr). The first color filter CF1 may overlap the first light emitting area EA1 and the light blocking area (e.g., the light blocking area BA in FIG. 3), and the first color filter CF1 may not overlap the second and third light emitting areas EA2 and EA3.

The second color filter CF2 may selectively transmit light of the second color (e.g., green light Lg). The second color filter CF2 may overlap the second light emitting area EA2 and the light blocking area, and the second color filter CF2 may not overlap the first and third light emitting areas EA1 and EA3.

The third color filter CF3 may selectively transmit light of the third color (e.g., blue light Lb). The third color filter CF3 may overlap the third light emitting area EA3 and the light blocking area, and the third color filter CF3 may not overlap the first and second light emitting areas EA1 and EA2.

The second protective layer PL2 may be disposed under the color filter layer. The second protective layer PL2 can prevent contamination of the color filter layer by blocking external impurities. In an embodiment, for example, the second protective layer PL2 may include an inorganic material such as silicon oxide, silicon nitride, silicon oxynitride, or the like. These can be used alone or in combination with each other.

The filling layer 300 may be disposed between the lower structure 100 and the upper structure 200. That is, the filling layer 300 may fill the empty space between the lower structure 100 and the upper structure 200.

Embodiments where the display device DD is an organic light emitting display device (OLED) are described above, but the embodiments of the disclosure are not limited thereto. In another embodiment, for example, the display device DD may include a liquid crystal display device (LCD), a field emission display device (FED), a plasma display device (PDP), or an electrophoretic display device (EPD).

In an embodiment, as shown in FIG. 4, the display device DD may have a structure including two substrates, but embodiments of the disclosure are not limited thereto. In an embodiment, for example, the display device DD may have a single substrate structure including one substrate. In such an embodiment, the bank layer BL, the light control layer, and the color filter layer may be sequentially formed directly on the encapsulation layer ENC.

FIG. 8 is a graph illustrating the impact margin versus the angle at which the bank layer is tilted.

Referring to FIGS. 4, 7, and 8, the impact margin increase that can be secured in the inkjet process of forming a light control pattern according to the inclined angle θ of the bank layer BL was measured. At this time, the height of the bank layer BL was about 7 micrometers.

As a result, it can be confirmed that when the bank layer BL is the inclined angle θ of about 90 degrees, the impact margin increase is about 0. On the other hand, it can be confirmed that when the inclined angle θ of the bank layer BL is less than about 90 degrees and greater or equal to about 50 degrees, the impact margin increase satisfies a value of greater than about 0 micrometers and less than about 6 micrometers. Here, the impact margin increase corresponds to the first interval MR1 or the second interval MR2 in FIG. 7.

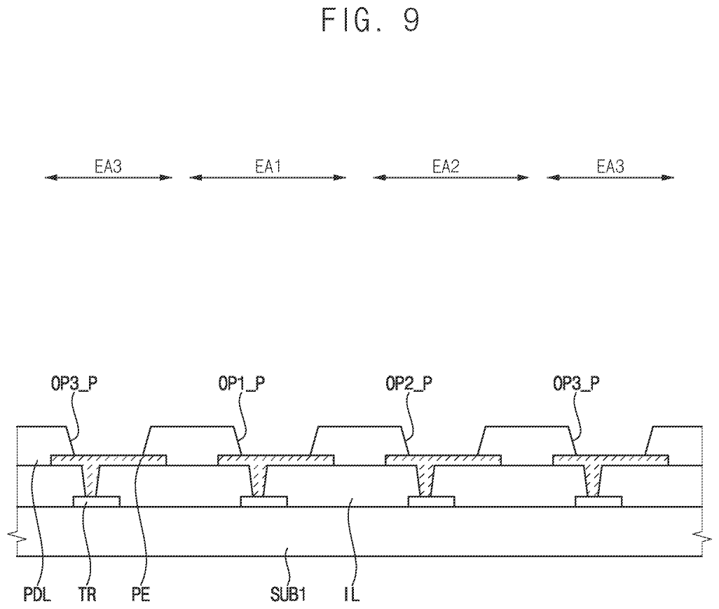

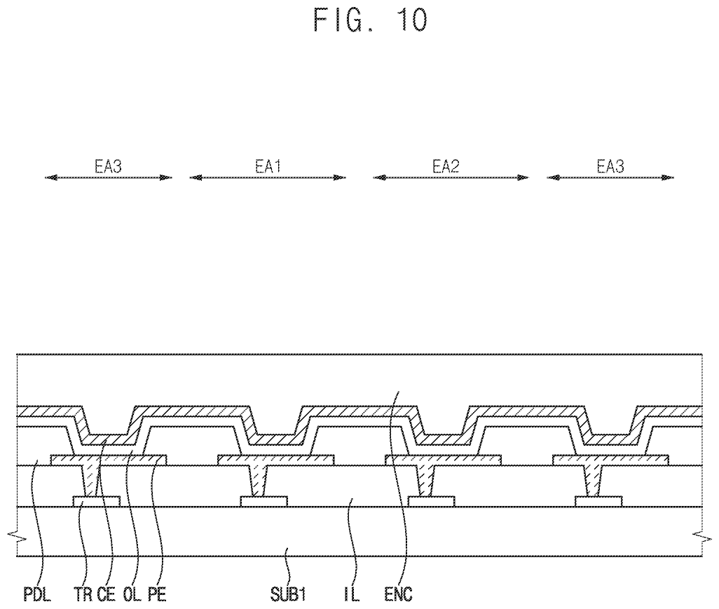

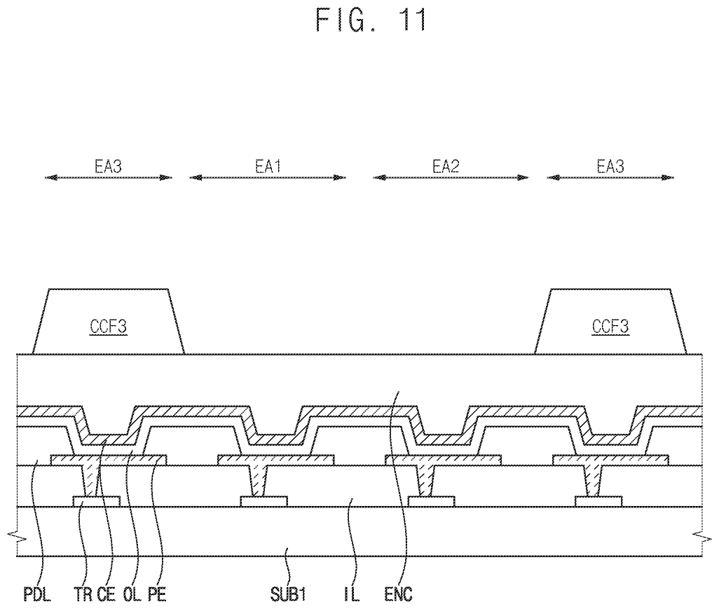

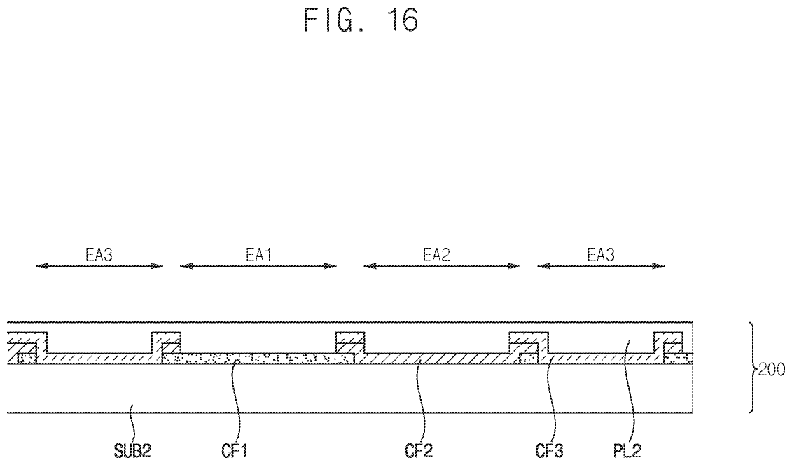

FIGS. 9, 10, 11, 12, 13, 14, 15, 16, and 17 are cross-sectional views illustrating an embodiment of the method of manufacturing the display device of FIG. 4. Specifically, FIGS. 9, 10, 11, 12, 13, and 14, are cross-sectional views illustrating the method of manufacturing the lower structure 100 of FIG. 4, and FIGS. 15, 16, and 17 are cross-sectional views illustrating the method of manufacturing the upper structure 200 of FIG. 4.

Referring to FIG. 9, in an embodiment of the method of manufacturing the display device, the semiconductor element TR, the insulating structure IL, the pixel electrode PE, and the pixel defining layer PDL may be sequentially formed on the first substrate SUB1. The insulating structure IL may be formed to cover the semiconductor element TR. The pixel electrode PE may be connected to the semiconductor element TR through a contact hole formed by removing a part of the insulating structure IL.

In an embodiment, after a preliminary pixel defining layer is formed on the insulating structure IL, a part of the preliminary pixel defining layer may be removed through an etching process. Accordingly, the pixel defining layer PDL may be formed to define the first opening OP1_P exposing at least a part of the pixel electrode PE in the first light emitting area EA1, the second opening OP1_P exposing at least a part of the pixel electrode PE in the second light emitting area EA2, and the third opening OP3_P exposing at least a part of the pixel electrode PE in the third light emitting area EA3.

Referring to FIG. 10, the organic layer OL may be formed on the pixel electrode PE and the pixel defining layer PDL. The common electrode CE may be formed on the organic layer OL. The organic layer OL and the common electrode PE may be formed on the entire surface of a display area (e.g., the display area DA of FIGS. 1, 2, and 3). Accordingly, a light emitting element layer including the pixel electrode PE, the organic layer OL, and the common electrode CE may be formed.

The encapsulation layer ENC may be formed on the common electrode CE. The encapsulation layer ENC may include at least one inorganic layer and at least one organic layer.

Referring to FIG. 11, a photosensitive organic layer may be formed on the encapsulation layer ENC. In an embodiment, for example, the photosensitive organic layer may include a base resin including a transparent organic material, i.e., an organic material with high light transparency and scattering particles dispersed in the base resin. In this case, the photosensitive organic layer might not include quantum dots.

In an embodiment, the photosensitive organic layer may be patterned through a photolithography process to form the third light control pattern CCF3 overlapping the third light emitting area EA3. In this case, the cross-section of the third light control pattern CCF3 may have a tapered shape having a width decreasing as being away from the encapsulation layer ENC or the first substrate SUB1.

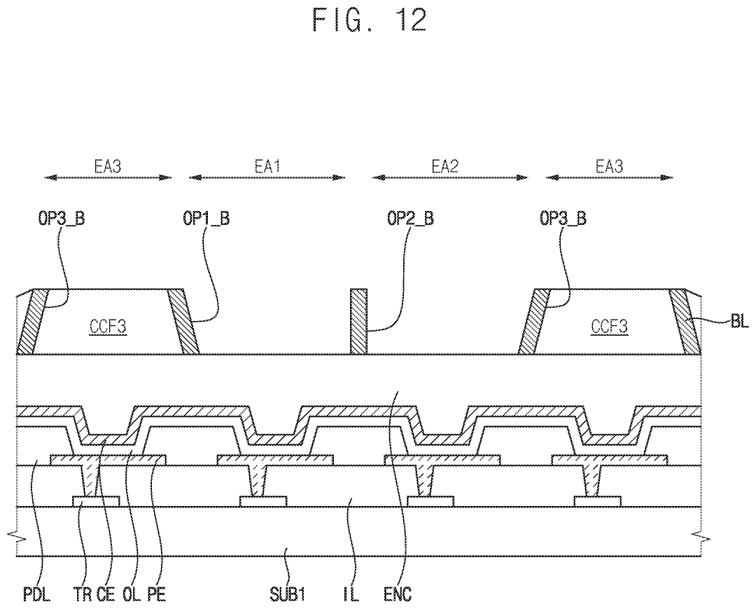

Referring to FIG. 12, a preliminary bank layer may be formed on the encapsulation layer ENC. In an embodiment, for example, the preliminary bank layer may include an organic material. In an embodiment, the preliminary bank layer may be patterned through a photolithography process to form the bank layer BL overlapping the light blocking area (e.g., the light blocking area BA of FIG. 3). The bank layer BL may surround the side surface of the third light control pattern CCF3.

In an embodiment, the bank layer BL may include a part contacting the side surface of the third light control pattern CCF3 and inclined at a predetermined angle with respect to the plane parallel to the upper surface of the first substrate SUB1.

The first opening OP1_B overlapping the first light emitting area EA1, the second opening OP2_B overlapping the second light emitting area EA2, and the third opening OP3_B overlapping the third light emitting area EA3 may be defined in the bank layer BL. The third light control pattern CCF3 may be provided in the third opening OP3_B.

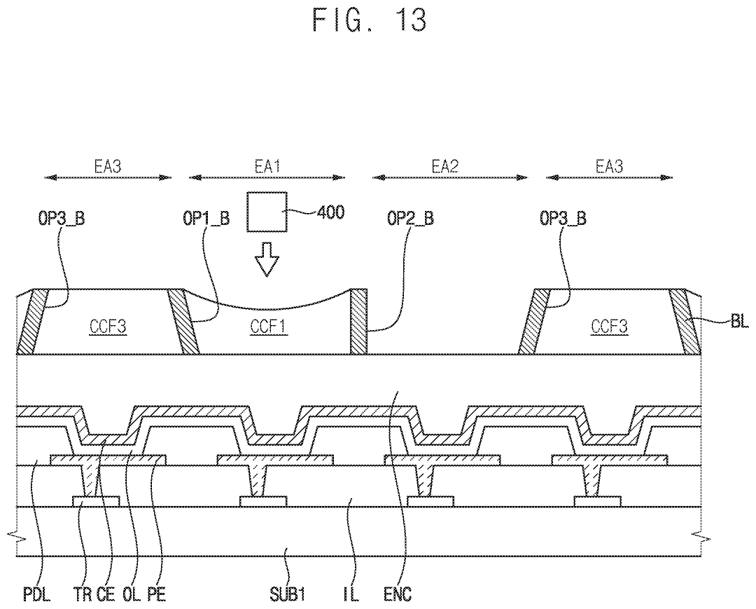

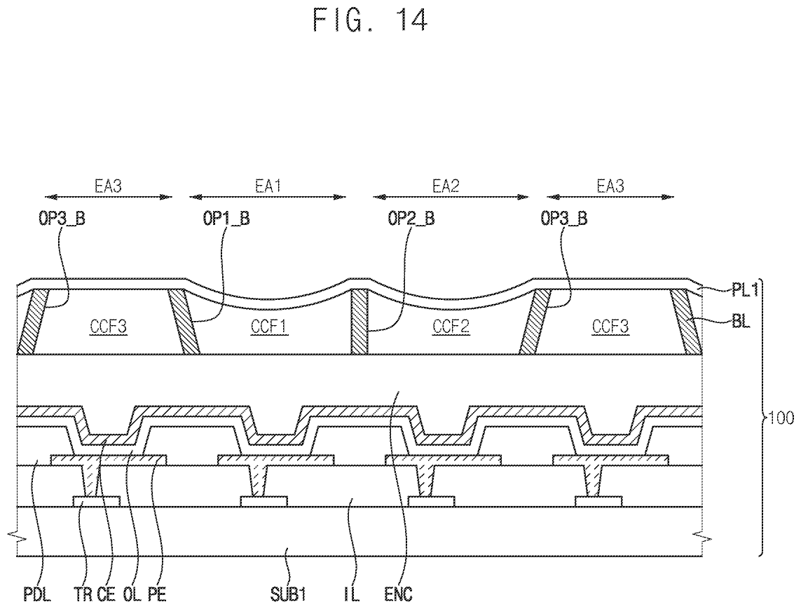

Referring to FIG. 13, an inkjet apparatus 400 may spray or drop a first ink composition into the first opening OP1_B. Here, the first ink composition may be a material which forms the first light control pattern CCF1. The inkjet apparatus 400 may repeatedly spray or drop the first ink composition into the first opening OP1_B to form the first light control pattern CCF1.

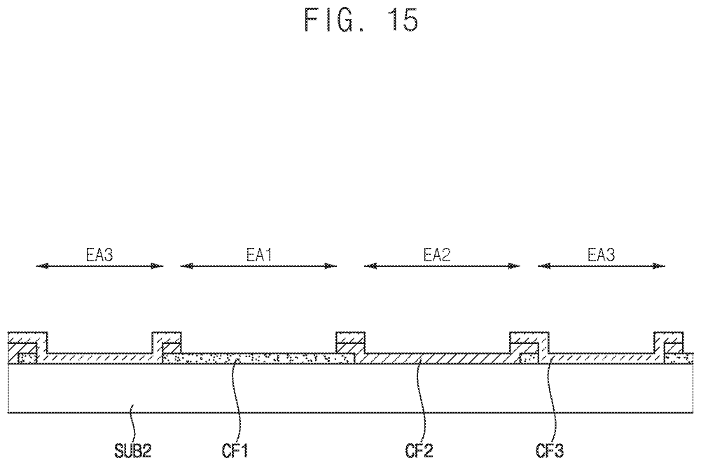

Referring to FIG. 14, after the inkjet apparatus 400 moves onto the second opening OP2_B, inkjet apparatus 400 may repeatedly spray or drop a second ink composition into the second opening OP2_B to form the second light control pattern CCF2. Here, the second ink composition may be a material which forms the second light control pattern CCF2. The first protective layer PL1 may be formed on the bank layer BL and the first, second, and third light control patterns CCF1, CCF2, and CCF3.

That is, in an embodiment, the first and second light control patterns CCF1 and CCF2 may be formed through an inkjet process.

Accordingly, the lower structure 100 shown in FIG. 4 may be formed.

Referring to FIG. 15, the first color filter CF1 may be formed on the second substrate SUB2. The first color filter CF1 may be formed in the first light emitting area EA1 and the light blocking area. The first color filter CF1 may be a red color filter which transmits red light. In an embodiment, for example, the first color filter CF1 may be formed from a red pigment and/or a color filter composition including a red pigment.

The second color filter CF2 may be formed on the second substrate SUB2 and the first color filter CF1. The second color filter CF2 may be formed in the second light emitting area EA2 and the light blocking area. The second color filter CF2 may be a green color filter which transmits green light. In an embodiment, for example, the second color filter CF2 may be formed from a green pigment and/or a color filter composition including a green pigment.

The third color filter CF3 may be formed on the second color filter CF2 and the second substrate SUB2. The third color filter CF3 may be formed in the third light emitting area EA3 and the light blocking area. The third color filter CF3 may be a blue color filter which transmits blue light. The third color filter CF3 may be formed from a blue pigment and/or a color filter composition including a blue pigment.

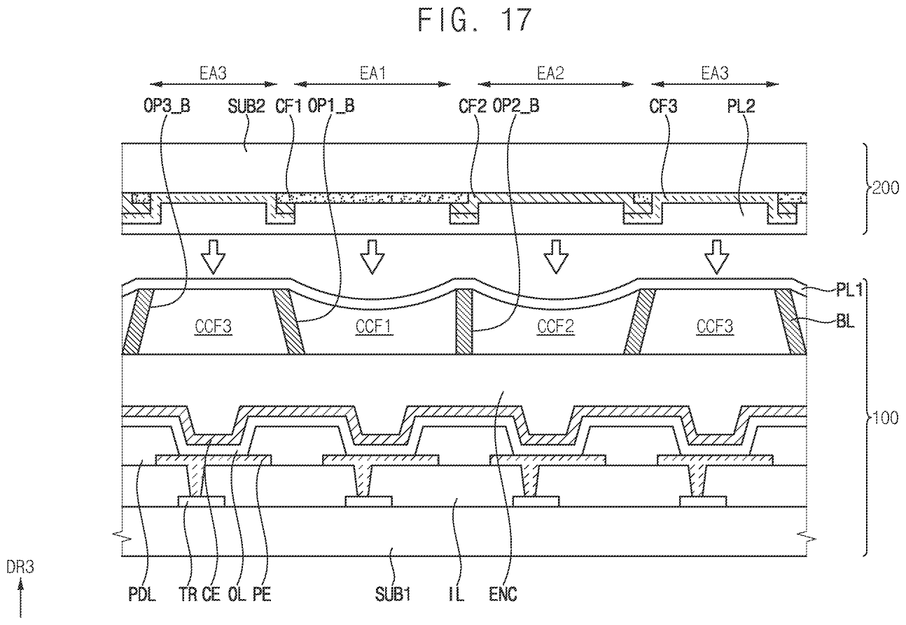

Referring to FIG. 16, the second protective layer PL2 may be formed on the first, second, and third color filters CF1, CF2, and CF3. Accordingly, the upper structure 200 shown in FIG. 4 may be formed.

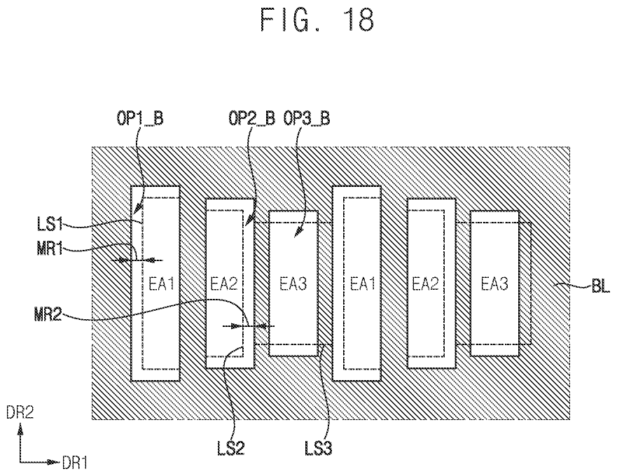

Referring to FIGS. 4 and 17, the lower structure 100 and the upper structure 200 may be combined. Specifically, the lower structure 100 and the upper structure 200 may be coupled through a sealing portion (e.g., the sealing portion 350 of FIG. 2). As the lower structure 100 and the upper structure 200 are combined, the display device DD shown in FIG. 4 may be manufactured.

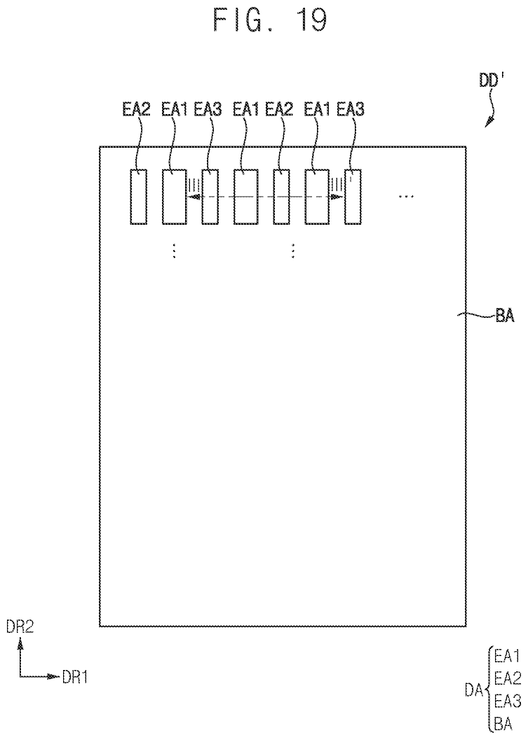

FIG. 18 is a plan view illustrating another example of the bank layer of FIG. 4.

Hereinafter, any repetitive detailed descriptions of the same or like features of the bank layer BL as those described above with reference to FIGS. 4 and 7 will be omitted or simplified.

In an embodiment, a first opening OP1_B overlapping the first light emitting area EA1, a second opening OP2_B overlapping the second light emitting area EA2, and a third opening OP3_B overlapping the third light emitting area EA3 may be defined in the bank layer BL.

In the plan view, the area of a first bottom surface LS1 of the first opening OP1_B may be different from the area of a first top surface of the first opening OP1_B, the area of a second bottom surface LS2 of the second opening OP2_B may be different from the area of a second top surface of the second opening OP2_B, and the area of a third bottom surface LS3 of the third opening OP3_B may be different from the area of a third top surface of the third opening OP3_B. In an embodiment, the area of the first bottom surface LS1 of the first opening OP1_B may be smaller than the area of the first top surface of the first opening OP1_B, the area of the second bottom surface LS2 of the second opening OP2_B may be smaller than the area of the second top surface of the second opening OP2_B, and the area of the third bottom surface LS3 of the third opening OP3_B may be larger than the area of the third top surface of the third opening OP3_B.

Here, the edge of the third bottom surface LS3 may coincide or be aligned with the edge of the first top surface and the edge of the second top surface located in the left and right sides of the third opening OP3.

In an embodiment, for example, in the plan view, the first top surface may protrude from the side surface of the first bottom surface LS1 in a direction opposite to the first direction DR1, the second top surface may protrude from the side of the second bottom surface LS2 in a direction opposite to the first direction DR1, the second direction DR2, and in a direction opposite to the second direction DR2, and the third bottom surface LS3 may protrude from both side surfaces of the third top surface in the first direction DR1 and in a direction opposite to the first direction DR1. In addition, the third bottom surface LS3 may protrude from both side surfaces of the third top surface in the second direction DR2 and in a direction opposite to the second direction DR2.

In an embodiment, as shown in FIG. 18, the area difference between the first top surface and the first bottom surface LS1 may be relatively increased compared to that shown in FIG. 4, and the area difference between the second top surface and the second bottom surface LS2 may be relatively increased compared to that shown in FIG. 4. That is, in such an embodiment, the area of the first top surface may further increase, and the area of the second top surface may further increase. Accordingly, in such an embodiment, the amount of inkjet impact margin that can be secured in the inkjet process of forming the first and second light control patterns CCF1 and CCF2 may further increase.

In addition, the area of the third top surface may be relatively increased compared to that shown in FIG. 4. Accordingly, in such an embodiment, the emission efficiency can increase in the third light emitting area EA3.

FIG. 19 is a plan view illustrating a display device according to an embodiment of the disclosure.

Hereinafter, any repetitive detailed descriptions of the same or like elements as those of the display device DD described above with reference to FIG. 3 will be omitted or simplified.

Referring to FIG. 19, a display device DD′ according to an embodiment of the disclosure may include a display area DA, and the display area DA may include a plurality of light emitting areas and a light blocking area BA. Each of the light emitting areas may emit light. The light emitting areas may include a first light emitting area EA1, a second light emitting area EA2, and a third light emitting area EA3.

In an embodiment, the first light emitting area EA1 may be a red light emitting area which emits red light, the second light emitting area EA2 may be a green light emitting area which emits green light, and the third light emitting area EA3 may be a green light emitting area which emits blue light.

In an embodiment, the second light emitting area EA2 and the third light emitting area EA3 may be repeatedly arranged along each row line in an order of the second light emitting area EA2 and the third light emitting area EA3, and the first light emitting area EA1 may be located between the second and third light emitting areas EA2 and EA3. In an embodiment, for example, the second light emitting area EA2 and the third light emitting area EA3 may be repeatedly arranged in the first direction DR1 along a first row line in an order of the second light emitting area EA2 and the third light emitting area EA3, and the first light emitting area EA1 may be located between the second and third light emitting areas EA2 and EA3 in the first row line. In addition, the second light emitting area EA2 and the third light emitting area EA3 may be repeatedly arranged in the first direction DR1 along a second row line adjacent to the first row line in an order of the second light emitting area EA2 and the third light emitting area EA3, and the first light emitting area EA1 may be located between the second and third light emitting areas EA2 and EA3 in the second row line. This arrangement may be repeated up to a predetermined row line.

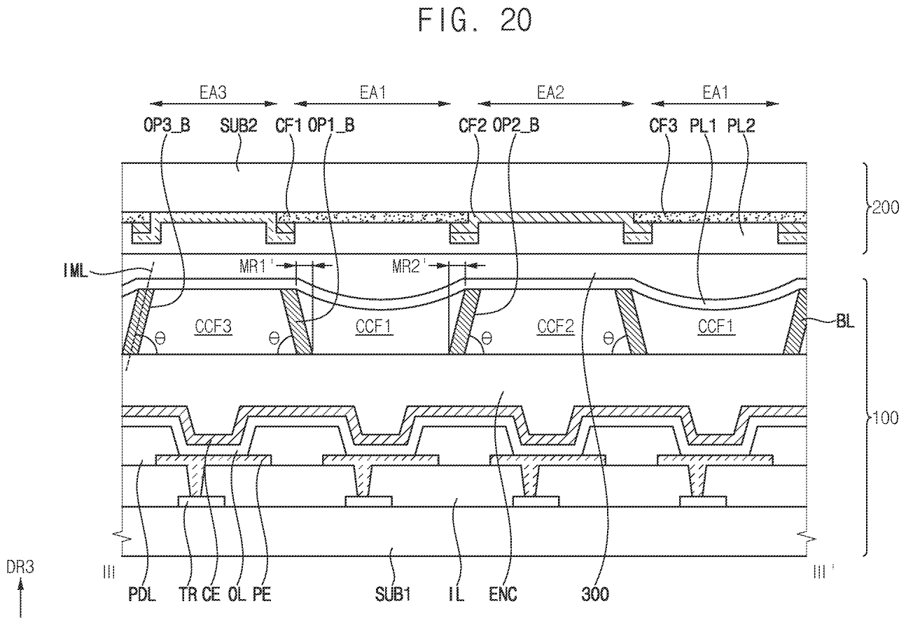

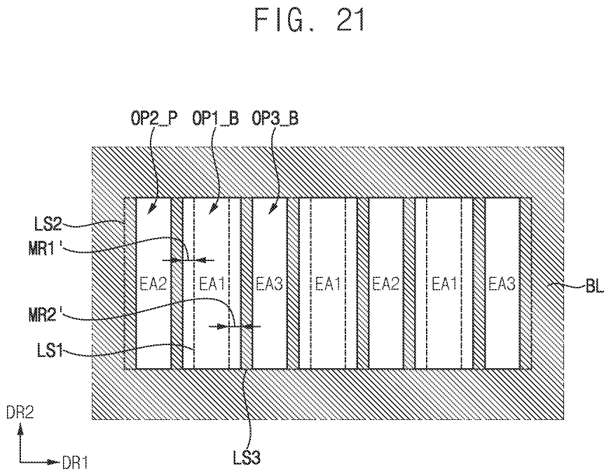

FIG. 20 is a cross-sectional view taken along line III-III′ of FIG. 19. FIG. 21 is a plan view illustrating an example of the bank layer of FIG. 20.

Referring to FIGS. 19, 20, and 21, the display device DD′ according to an embodiment of the disclosure may include a lower structure 100, a filling layer 300, and an upper structure 200. Such an embodiment of the display device DD′ shown in FIGS. 19, 20, and 21 may be substantially the same as or similar to the embodiments of the display device DD described above with reference to FIGS. 4 and 7 except for the bank layer BL. Hereinafter, any repetitive detailed descriptions of the same or like elements as those described above will be omitted.

The bank layer BL may be disposed on the encapsulation layer ENC. The bank layer BL may overlap a light blocking area (e.g., the light blocking area BA of FIG. 3). A space capable of accommodating materials forming the first, second, and third light control patterns CCF1, CCF2, and CCF3 may be defined in the bank layer BL.

In an embodiment, a first opening OP1_B overlapping the first light emitting area EA1, a second opening OP2_B overlapping the second light emitting area EA2, and a third opening OP3_B overlapping the third light emitting area EA3 may be defined in the bank layer BL.

The light control layer may be disposed on the encapsulation layer ENC. The light control layer may include the first light control pattern CCF1, a second light control pattern CCF2, and the third light control pattern CCF3. The first light control pattern CCF1 may overlap the first light emitting area EA1, the second light control pattern CCF2 may overlap the second light emitting area EA2, and the third light control pattern CCF3 may overlap the third light emitting area EA3. In an embodiment, the first light control pattern CCF1 may be disposed in the first opening OP1_B, the second light control pattern CCF2 may be disposed in the second opening OP2_B, and the third light control pattern CCF3 may be disposed in the third opening OP3_B.

The first light control pattern CCF1 may include a base resin including a transparent organic material, i.e., an organic material with high light transparency and quantum dots dispersed in the base resin. In an embodiment, the second and third light control patterns CCF2 and CCF3 may include a base resin including a transparent organic material, i.e., an organic material with high light transparency and scattering particles dispersed in the base resin. In such an embodiment, the second and third light control patterns CCF2 and CCF3 might not include quantum dots.

In an embodiment, the first light control pattern CCF1 may be formed through an inkjet process, and the second and third light control patterns CCF2 and CCF3 may be formed through a photolithography process. In such an embodiment, the second and third light control patterns CCF1 and CCF3 may be formed before the bank layer BL, and the first light control pattern CCF1 may be formed after the bank layer BL.

In an embodiment, a cross-section of each of the second and third light control patterns CCF3 may have a tapered shape having a width decreasing as being away from the encapsulation layer ENC or the first substrate SUB1.

In an embodiment, when the bank layer BL includes an organic material, a metal layer may be further disposed between the bank layer BL and the second light control pattern CCF2, and between the bank layer BL and the third light control pattern CCF3. In another embodiment, when the bank layer BL includes an organic material, a metal layer may be further disposed between the bank layer BL and the first light control pattern CCF1, between the bank layer BL and the second light control pattern CCF2, and between the bank layer BL and the third light control pattern CCF3.

A part of the bank layer BL may be inclined at a predetermined angle θ with respect to a plane parallel to the upper surface of the first substrate SUB1. In an embodiment, the bank layer BL may include a first part located between the first light control pattern CCF1 and the third light control pattern CCF3 and inclined at the predetermined angle θ toward the third light control pattern CCF3, and a second part located between the first light control pattern CCF1 and the second light control pattern CCF2 and inclined at the predetermined angle θ toward the second light control pattern CCF2.

That is, as the side surfaces of each of the second and third light control patterns CCF2 and CCF3 have a tapered shape, the first part and the second part of the bank layer BL may be inclined at the predetermined angle θ.

In an embodiment, the predetermined angle θ may be defined as the angle between an imaginary line IML passing through the center of the first part (or the second part) of the bank layer BL and parallel to the side surface of the first part (or the second part) of the bank layer BL, and a plane parallel to the upper surface of the first substrate SUB1.

The predetermined angle θ may be less than about 90 degrees. That is, the predetermined angle θ may be an acute angle. In an embodiment, the predetermined angle θ may be greater than or equal to about 60 degrees and less than about 90 degrees. If the predetermined angle θ is less than about 60 degrees, the emission efficiency of the third light emitting area EA3 may decrease. If the predetermined angle θ is greater than 90 degrees, the inkjet impact margin may not be secured.

A part of the bank layer BL may have a lower width and an upper width that are substantially the same as each other. In an embodiment, the width of a lower part of the part of the bank layer BL located between the first, second, and third light control patterns CCF1, CCF2, and CCF3 may be substantially the same as the width of an upper part of the part of the bank layer BL located between the first, second, and third light control patterns CCF1, CCF2, and CCF3. That is, the width of the part of the bank layer BL located between the first, second, and third light control patterns CCF1, CCF2, and CCF3 may be constant. Accordingly, color mixing between the first, second, and third light emitting areas EA1, EA2, and EA3 can be prevented.

In the plan view, the area of a first bottom surface LS1 of the first opening OP1_B may be different from the area of a first top surface of the first opening OP1_B, the area of a second bottom surface LS2 of the second opening OP2_B may be different from the area of a second top surface of the second opening OP2_B, and the area of a third bottom surface LS3 of the third opening OP3_B may be different from the area of a third top surface of the third opening OP3_B. In an embodiment, the area of the first bottom surface LS1 of the first opening OP1_B may be smaller than the area of the first top surface of the first opening OP1_B, the area of the second bottom surface LS2 of the second opening OP2_B may be larger than the area of the second top surface of the second opening OP2_B, and the area of the third bottom surface LS3 of the third opening OP3_B may be larger than the area of the third top surface of the third opening OP3_B.

Here, the edge of the second bottom surface LS2 may coincide or be aligned with the edge of the first regular surface located in the left and right of the second opening OP2_B. The edge of the third bottom surface LS3 may coincide or be aligned with the edge of the first top surface located in the left and right of the third opening OP3_B.

In an embodiment, for example, in the plan view, the first top surface may protrude from the side surface of the first bottom surface LS1 in the first direction DR1 and a direction opposite to the first direction DR1, the second top surface may protrude from both side surfaces of the second bottom surface LS2 in the first direction DR1 and the direction opposite to the first direction DR1, and the third bottom surface LS3 may protrude from both side surfaces of the third top surface in the first direction DR1 and in the direction opposite to the first direction DR1. However, embodiments of the disclosure are not limited thereto.

In the plan view, a first interval MR1′, where the first top surface of the first opening OP1_B protrudes from a first side surface of the first bottom surface LS1 in the direction opposite to the first direction DR1, and a second interval MR2′, where the first top surface of the first opening OP1_B protrudes from a second side surface of the first bottom surface LS1 in the first direction DR1, may refer to the inkjet impact margin increase which can be secured in the inkjet process of forming the first light control pattern CCF1. The first interval MR1′ may refer to the shortest distance between the edge of the first top surface and the first side surface of the first bottom surface LS1, and the second interval MR2′ may refer to the shortest distance between the edge of the first top surface and the second side surface of the second side surface of the second bottom surface LS2.

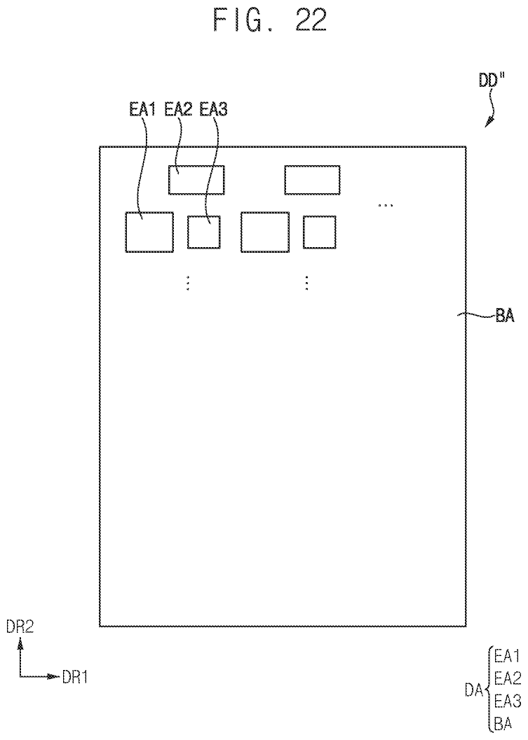

FIG. 22 is a plan view illustrating a display device according to an embodiment of the disclosure.

An embodiment of a display device DD″ shown in FIG. 22 may be substantially the same as or similar to the embodiments of the display device DD described above with reference to FIG. 3 except for the arrangement of the first light emitting area EA1, the second light emitting area EA2, and the third light emitting area EA3. Hereinafter, any repetitive detailed descriptions of the same or like elements as those of the display device DD described with reference to FIG. 3 will be omitted or simplified.

Referring to FIG. 22, the display device DD″ according to an embodiment of the disclosure may include a display area DA, and the display area DA may include a plurality of light emitting areas and a light blocking area BA. Each of the light emitting areas may emit light. The light emitting areas may include a first light emitting area EA1, a second light emitting area EA2, and a third light emitting area EA3.

In an embodiment, the first light emitting area EA1 may be a red light emitting area which emits red light, the second light emitting area EA2 may be a green light emitting area which emits green light, and the third light emitting area EA3 may be a blue light emitting area. which emits blue light.

In an embodiment, the second light emitting area EA2 may be repeatedly arranged along the first direction DR1 in odd-numbered row lines, the first light emitting area EA1 and the third light emitting area EA3 may be repeatedly arranged along the first direction DR1 in even-numbered rows in an order of the first light emitting area EA1 and the third light emitting area EA3, and the second light emitting area EA2 may face the third light emitting area EA3 in the second direction DR2. In an embodiment, for example, the second light emitting area EA2 may be repeatedly arranged along the first direction DR1 in a first row line, and the first light emitting area EA1 and the third light emitting area EA3 may be repeatedly arranged in a second row line adjacent to the first row line in the first direction DR1 in an order of the first light emitting area EA1 and the third light emitting area EA3. This arrangement may be repeated up to a predetermined row line.

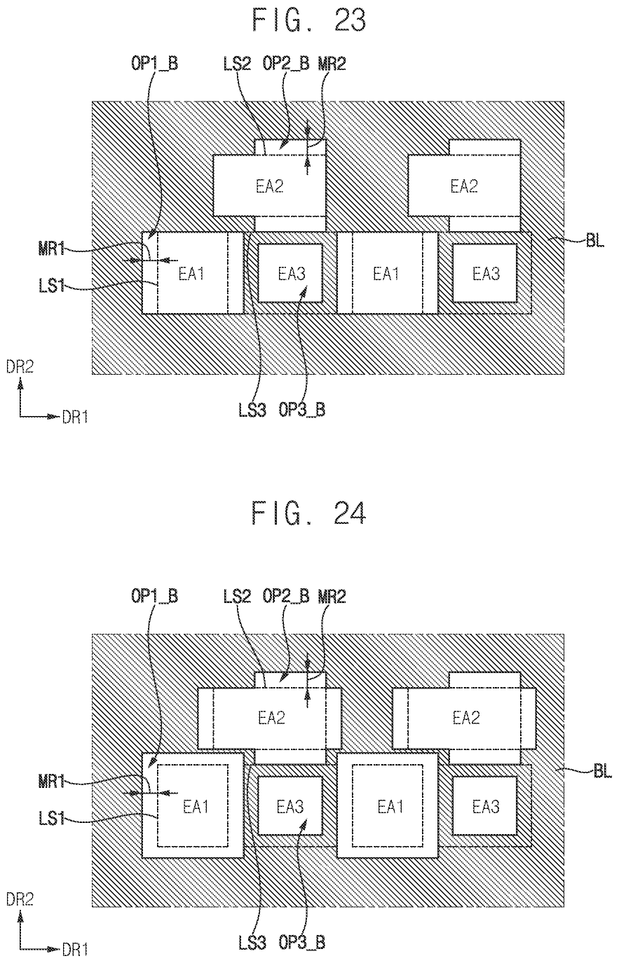

FIG. 23 is a plan view illustrating an example of a bank layer. FIG. 24 is a plan view illustrating another example of a bank layer.

Hereinafter, any repetitive detailed descriptions of the same or like features of the bank layer B1 as those of the bank layer BL described with reference to FIGS. 4 and 7 will be omitted or simplified.

In an embodiment, a first opening OP1_B overlapping the first light emitting area EA1, a second opening OP2_B overlapping the second light emitting area EA2, and a third opening OP3_B overlapping the third light emitting area EA3 may be defined in the bank layer BL. The arrangement of the first, second, and third light emitting areas EA1, EA2, and EA3 of FIGS. 23 and 24 may correspond to the arrangement of the first, second, and third light emitting areas EA1, EA2, and EA3 of FIG. 22.

A first light control pattern may be disposed in the first opening OP1_B, a second light control pattern may be disposed in the second opening OP2_B, and a third light control pattern may be disposed in the third opening OP3_B. A material, a shape, and the like of the first, second, and third light control patterns may be substantially the same as the first, second, and third light control patterns CCF1, CCF2, and CCF3 of FIG. 4, respectively.

In the plan view, the area of a first bottom surface LS1 of the first opening OP1_B may be different from the area of a first top surface of the first opening OP1_B, the area of a second bottom surface LS2 of the second opening OP2_B may be different from the area of a second top surface of the second opening OP2_B, and the area of a third bottom surface LS3 of the third opening OP3_B may be different from the area of a third top surface of the third opening OP3_B. In an embodiment, the area of the first bottom surface LS1 of the first opening OP1_B may be smaller than the area of the first top surface of the first opening OP1_B, the area of the second bottom surface LS2 of the second opening OP2_B may be smaller than the area of the second top surface of the second opening OP2_B, and the area of the third bottom surface LS3 of the third opening OP3_B may be larger than the area of the third top surface of the third opening OP3_B.

Here, the edge of the third bottom surface LS3 may coincide or be aligned with the edge of the first top surface and the edge of the second top surface located in the top, bottom, left, and right of the third opening OP3.

In an embodiment, for example, as shown in FIG. 23, in the plan view, the first top surface may protrude from the side surface of the first bottom surface LS1 in the first direction DR1 and in a direction opposite to the first direction DR1, the second top surface may protrude from the side surface of the second bottom surface LS2 in the second direction DR2 and in a direction opposite to the second direction DR2, and the third bottom surface LS3 may protrude in all directions (e.g., the first direction DR1, the direction opposite to the first direction DR1, the second direction DR2, and the direction opposite to the second direction DR2) from the edge of the third top surface.

Alternatively, as shown in FIG. 24, in the plan view, the first top surface may protrude in the all directions from the side surface of the first bottom surface LS1, the second top surface may protrude from in the all directions from the side surface of the second bottom surface LS2, and the third bottom surface LS3 may protrude in the all directions from the edge of the third top surface. However, embodiments of the disclosure are not limited thereto.

In the plan view, a first interval MR1, where the first top surface of the first opening OP1_B protrudes from the side surface of the first bottom surface LS1, may refer to the inkjet impact margin which can be secured in the inkjet process of forming the first light control pattern CCF1, and a second interval MR2, where the second top surface of the second opening OP2_B protrudes from the side surface of the second bottom surface LS2, may refer to the inkjet impact margin which can be secured in the inkjet process of forming the second light control pattern CCF2.

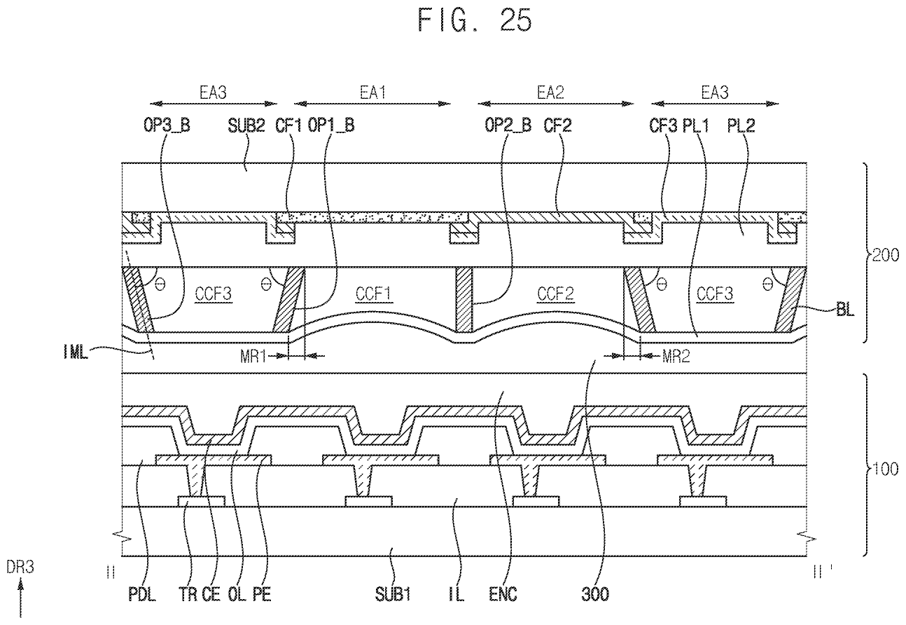

FIG. 25 is a cross-sectional view illustrating another example of FIG. 4.

Referring to FIG. 25, the display device DD according to an embodiment of the invention may include a lower structure 100, a filling layer 300, and an upper structure 200. Such an embodiment of the display device DD shown in FIG. 25 may be substantially the same as or similar to the embodiments of the display device DD described above with reference to FIG. 4 except for the position of the bank layer BL and the light control layer. Hereinafter, any repetitive detailed descriptions of the same or like elements as those described above will be omitted.

The lower structure 100 may include a first substrate SUB1, a semiconductor element TR, an insulating structure IL, a pixel defining layer PDL, a pixel electrode PE, an organic layer OL, a common electrode CE, and an encapsulation layer ENC. The semiconductor element TR, the insulating structure IL, the pixel defining layer PDL, the pixel electrode PE, the organic layer OL, the common electrode CE, and the encapsulation layer ENC may be sequentially disposed on the first substrate SUB1 in the third direction DR3.

The upper structure 200 may include a second substrate SUB2, a color filter layer, a second protective layer PL2, the bank layer BL, a light control layer, and a first protective layer PL1. The color filter layer, the second protective layer PL2, the bank layer BL, the light control layer, and the first protective layer PL1 may be sequentially disposed on the second substrate SUB2 in a direction opposite the third direction DR3.

The color filter layer may include a first color filter CF1, a second color filter CF2, and a third color filter CF3. In addition, the light control layer may include a first light control pattern CCF1, a second light control pattern CCF2, and a third light control pattern CCF3.

In an embodiment, as described above, the bank layer BL and the light control layer may be included in the upper structure 200. That is, the bank layer BL and the light control layer may not be included in the lower structure 100.

In addition, embodiments of the display device DD′ of FIGS. 19 and 20 and the display device DD″ of FIG. 22 may be modified in a way such that the bank layer BL and the light control layer are not included in the lower structure 100 but included in the upper structure 200 as shown in FIG. 25.

Referring back to FIGS. 1, 2, 3, 4, 5, 6, and 7 and 18, 19, 20, 21, 22, 23, 24, and 25, the display device according to embodiments of the disclosure may include the first light control pattern CCF1 overlapping the first light emitting area EA1 which emits red light, the second light control pattern CCF2 overlapping the second light emitting area EA2 which emits green light, the third light control pattern CCF3 overlapping the third light emitting area EA3 which emits blue light, and the bank layer BL surrounding the first, second, and third light control patterns CCF, CCF2, and CCF3. In such embodiments, a part of the bank layer BL may be inclined at a predetermined angle toward a light control pattern (e.g., the third light control pattern CCF3 or the second and third control pattern CCF2 and CCF3) formed through a photolithography process which does not include quantum dots. Accordingly, in process of forming the light control pattern through an inkjet process, a sufficient inkjet impact margin can be secured in the inkjet process. In addition, a high-resolution display device can be implemented.

Embodiments of the disclosure can be applied to various display devices such as display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a first light emitting area, a second light emitting area, and a third light emitting area, wherein the first to third light emitting areas emit light of different colors, respectively;
a light emitting element layer disposed on the substrate and overlapping the first, second, and third light emitting areas;
a first light control pattern disposed on the light emitting element layer and overlapping the first light emitting area, wherein the first light control pattern includes a first base resin and first quantum dots dispersed in the first base resin;
a second light control pattern disposed on the light emitting element layer and overlapping the second light emitting area;
a third light control pattern disposed on the light emitting element layer and overlapping the third light emitting area; and
a bank layer including a first part inclined at a first angle toward the third light control pattern with respect to a plane parallel to an upper surface of the substrate and located between the first light control pattern and the third light control pattern, wherein the bank layer surrounds the first, second, and third light control patterns in a plan view.

2. The display device of claim 1, wherein the bank layer further includes:
a second part located the second light control pattern and the third light control pattern, and inclined at a second angle toward the third light control pattern with respect to the plane parallel to the upper surface of the substrate.

3. The display device of claim 2, wherein each of the first and second angles is greater than or equal to about 60 degrees and less than about 90 degrees.

4. The display device of claim 1, wherein a part of the bank layer located between the first light control pattern and the second light control pattern is perpendicular to the upper surface of the substrate.

5. The display device of claim 2, wherein
a first opening, in which the first light control pattern is disposed, a second opening, in which the second light control pattern is disposed, and a third opening, in which the third light control pattern is disposed, are defined in the bank layer,
an area of a first bottom surface of the first opening is smaller than an area of a first top surface of the first opening in the plan view,
an area of a second bottom surface of the second opening is smaller than an area of a second top surface of the second opening in the plan view, and
an area of a third bottom surface of the third opening is larger than an area of a third top surface of the third opening in the plan view.

6. The display device of claim 1, wherein a cross-section of the third light control pattern has a tapered shape.

7. The display device of claim 1, wherein a width of a lower part of a part of the bank layer located between the first, second, and third light control patterns is the same as a width of an upper part of the part of the bank layer located between the first, second, and third light control patterns.

8. The display device of claim 1, wherein
the first light emitting area is a red light emitting area which emits red light,
the second light emitting area is a green light emitting area which emits green light, and
the third light emitting area is a blue light emitting area which emits blue light.

9. The display device of claim 1, wherein the second light control pattern includes a second base resin and second quantum dots dispersed in the second base resin.

10. The display device of claim 1, wherein the third light control pattern includes a base resin including a transparent organic material with light transparency and scattering particles dispersed in the base resin.

11. The display device of claim 1, wherein the first light emitting area, the second light emitting area, and the third light emitting area are repeatedly arranged in each row line in an order of the first light emitting area, the second light emitting area, and the third light emitting area.

12. The display device of claim 1, wherein
the second light emitting areas are repeatedly arranged along a first direction in an odd-numbered row line,
the first light emitting area and the third light emitting area are repeatedly arranged along the first direction in an even-numbered row line in an order of the first light emitting area and the third light emitting area, and
the second light emitting area faces the third light emitting area in a second direction crossing the first direction.

13. A display device comprising:
a substrate including a first light emitting area, a second light emitting area, and a third light emitting area, wherein the first to third light emitting areas emit light of different colors, respectively;
a light emitting element layer disposed on the substrate and overlapping the first, second, and third light emitting areas;
a first light control pattern disposed on the light emitting element layer and overlapping the first light emitting area, wherein the first light control pattern includes a first base resin and first quantum dots dispersed in the first base resin;
a second light control pattern disposed on the light emitting element layer and overlapping the second light emitting area;
a third light control pattern disposed on the light emitting element layer and overlapping the third light emitting area; and
a bank layer surrounding the first, second, and third light control patterns in a plan view,
wherein the bank layer includes:
a first part inclined at a first angle toward the third light control pattern with respect to a plane parallel to an upper surface of the substrate and located between the first light control pattern and the third light control pattern; and
a second part inclined at a second angle toward the second light control pattern with respect to the plane parallel to the upper surface of the substrate and located between the first light control pattern and the second light control pattern.

14. The display device of claim 13, wherein each of the first and second angles is greater than about 60 degrees and less than about 90 degrees.

15. The display device of claim 13, wherein
a first opening, in which the first light control pattern is disposed, a second opening, in which the second light control pattern is disposed, and a third opening, in which the third light control pattern is disposed, are defined in the bank layer,
an area of a first bottom surface of the first opening is smaller than an area of a first top surface of the first opening in the plan view,
an area of a second bottom surface of the second opening is larger than an area of a second top surface of the second opening in the plan view, and
an area of a third bottom surface of the third opening is larger than an area of a third top surface of the third opening in the plan view.

16. The display device of claim 13, wherein a cross-section of each of the second and third light control patterns has a tapered shape.

17. The display device of claim 13, wherein each of the second and third light control patterns includes a base resin including a transparent organic material with light transparency and scattering particles dispersed in the base resin.

18. The display device of claim 13, wherein
the first light emitting area, the second light emitting area, and the third light emitting area are repeatedly arranged in each row line in an order of the first light emitting area, the second light emitting area, and the third light emitting area,
the second light emitting area and the third light emitting area are repeatedly arranged in each row line in an order of the second light emitting area and the third light emitting area, and
the first light emitting area is located between the second and third light emitting areas.

19. A method of manufacturing a display device, the method comprising:
forming a light emitting element layer on a substrate to overlap a first light emitting area, a second light emitting area, and a third light emitting area of the substrate, wherein the first to third light emitting areas emit light of different colors, respectively;
forming a third light control pattern on the light emitting element layer to overlap the third light emitting area;
forming a bank layer on the light emitting element layer, wherein the bank layer includes a part contacting a side surface of the third light control pattern and inclined at predetermined angle toward the third light control pattern with respect to a plane parallel to an upper surface of the substrate;
forming a first light control pattern on the light emitting element layer to overlap the first light emitting area, wherein the first light control pattern includes a first base resin and first quantum dots dispersed in the first base resin; and
forming a second light control pattern on the light emitting element layer to overlap the second light emitting area.

20. The method of claim 19, wherein
each of the forming the first light control pattern and the forming the second light control pattern includes using an inkjet process, and
the forming the third light control pattern includes using a photolithography process.
